(19) United States
(12) Patent Application Publication
(10) Pub. No.: US 2008/0315072 A1
(43) Pub. Date: Dec. 25, 2008

(54) APPARATUS AND METHOD FOR PRODUCING A REPRESENTATION OF AN OBJECT SCENE

(75) Inventors: Hans Dieter Tholl, Uhldingen (DE); Dirk Krogmann, Uhldingen (DE)

Correspondence Address: SCULLY SCOTT MURPHY & PRESSER, PC, 400 GARDEN CITY PLAZA, SUITE 300, GARDEN CITY, NY, 11530, US

(73) Assignee: BODENSEEWERK GERATETECHNIK GMBH, UBERLINGEN (DE)

(21) Appl. No.: 12/204,172

(22) Filed: Sep. 4, 2008

Related U.S. Application Data
(63) Continuation of application No. 10/844,851, filed on May 13, 2004.

(30) Foreign Application Priority Data
Sep. 20, 2003 (DE) 103 43 646.4

(51) Int. Cl. H01L 27/00

(52) U.S. Cl. 250/208.1

(57) ABSTRACT

An apparatus (2) and a method for producing a representation of an object scene, including a detector arrangement (12) with a plurality of detector units (20, 22) and an optical unit (4, 8) for producing the image of the object scene on the detector arrangement (12). To produce a high information content from representations of the object scene the apparatus (2) includes a filter unit (16, 26, 32, 72) arranged in an imaging beam path, with a first radiation filter raster with a first filter property and at least one second radiation filter raster with a second filter property different from the first filter property, wherein the radiation filter rasters penetrate each other, and a motion unit (100) for stepwise movement of an image of the radiation filter rasters relative to the detector arrangement (12).

### CROSS REFERENCE TO RELATED APPLICATION

This application is a continuation of U.S. patent application Ser. No. 10/844,851; filed on May 13, 2004, now pending.

### BACKGROUND OF THE INVENTION

1. Field of the Invention

The invention concerns an apparatus for producing a representation of an object scene, including a detector arrangement having a plurality of detector units and an optical unit for forming the image of the object scene on the detector arrangement. In addition the invention concerns a method of producing a representation of an object scene, in which the image of the object scene is produced by an optical unit on a detector arrangement having a plurality of detector units.

2. Discussion of the Prior Art

For the purposes of monitoring an area around a moving piece of equipment such as for example a vehicle, in particular an aircraft, it is known for the area around same to be scanned by means of detectors and suitable optical units and for the recorded electronic images to be transmitted for further evaluation. For that purpose it is advantageous to achieve a degree of resolution of the surrounding area which is as good as possible, with as few detectors as possible. For that purpose, it is known from DE 199 04 914 A1 for images of a plurality of object scene portions to be deflected successively through a suitable optical system with a high level of spatial resolution on to a detector array. The images can then be assembled to form an overall image. In that way, at the cost of the image-production rate, the spatial resolution in the composite overall field of view can be as high as in the individual field of vision. DE 199 04 914 A1 also proposes that in addition in each case only a small part from the respective image of an object scene portion is additionally produced with a screen raster on the detector array and that part is moved stepwise so that, after a number of recorded parts, the overall image can be completely made up from those parts. That makes it possible to multiply the level of resolution.

### SUMMARY OF THE INVENTION

The object of the present invention is to provide an apparatus and a method with which representations of an object scene can be produced with a high information content.

The object in respect of the apparatus is attained by an apparatus of the kind set forth in the opening part of this specification, which in accordance with the invention includes a filter unit arranged in an imaging beam path with a first radiation filter raster with a first filter property and at least one second radiation filter raster with a second filter property different from the first filter property, wherein the radiation filter rasters are in mutually penetrating relationship, and which includes a motion unit for stepwise motion of an image of the radiation filter rasters relative to the detector arrangement.

### ADVANTAGES OF THE INVENTION

The invention is based on the consideration that a high information content can be obtained from a representation of an object scene not just by a high level of resolution but also from analysis of the properties of the radiation emitted by the object scene. Those properties such as for example color, polarization or phase position of the radiation can be ascertained by means of a radiation filter arranged in the beam path which produces an image on the detector arrangement. Thus for example two images recorded in different colors show an object usually in differing intensities. In particular by subtraction of the two color images it is possible in that way to obtain information which could not be obtained or which would only be obtained with very great difficulty, by an increase in resolution. The same also applies for other filter properties such as polarization or phase position.

To produce color images of differing colors, it is known to produce a first color image by means of a first color filter and then a second color image by means of a second color filter. When using only one single detector arrangement on which both color images in each case are to be produced in their entirety, the first color filter has to be replaced with the second color filter to produce the second color image. The movement of the color filters, which is required for that purpose, results in a considerable delay in the speed of recording the color images. It is therefore desirable to be able to produce two or more images involving different filter properties on a detector arrangement with just one filter unit which does not need to be changed.

The arrangement of at least two radiation filter rasters involving different filter properties on the filter unit means that it is possible to record with the detector arrangement, for example simultaneously, a first image involving the first filter property through the regions of the first radiation filter raster and a second image involving the second filter property through the regions of the second radiation filter raster. Those images, each taken in itself, only partially reproduce the object scene. Now, by a very slight movement of the two radiation filter rasters, regions of the first radiation filter raster can be displaced to locations of the second radiation filter raster and regions of the second radiation filter raster can be displaced to locations of the first radiation filter raster. After the—for example simultaneous—recording of a third and a fourth image, the first and third images can then be assembled to form an overall image of a first filter property and the second and fourth images can be assembled to form an overall image of a second filter property. This results in two overall images involving different filter properties, for example a differing color, which can be passed for further evaluation.

The distance by which the radiation filter rasters have to be moved can correspond to a raster spacing of the radiation filter rasters. When producing very fine radiation filter rasters, a required movement of the radiation filter rasters, which as a result of the fine radiation filter rasters is only very slight, can be achieved in a simple and very precise manner by piezoelectric control elements which are inexpensive and simple to control and which in addition can provide for very fast movement of the radiation filter rasters. Production of the overall images formed in the filter property can be effected very quickly in that way. The differing coloration of color images or overall color images means that the spectrum of the incident radiation can be analysed by means for example of a matrix detector which is sensitive in a wider spectral band. It is possible to avoid technically complicated and expensive and slow multi-color detectors.

The representation of the object scene can be implemented purely electronically and does not have to be visually displayed or outputted. For that purpose it is sufficient if data at least partially representing the object scene can be read out of the detector arrangement and passed for further evaluation. In that case the object scene can be represented in distorted, altered or incomplete fashion. As mentioned above, the imaging procedure can be effected successively on the detector and does not have to be implemented in one image. The term raster can be used to denote a repetitive geometrical structure which can be selected in terms of shape and dimensions in a manner which appears appropriate for the man skilled in the art. Such a raster may be for example a line grating with parallel lines or stripes, a line network with mutually crossing lines or stripes or a chessboard raster. In the case of conventional two-dimensional matrix detectors, the filter unit desirably includes two or four radiation filter rasters, in which respect it is also possible to envisage a different number of radiation filter rasters involving a different filter property.

Mutual penetration of the radiation filter rasters occurs if the patterns of the radiation filter rasters interpenetrate in the beam path, the radiation filter rasters therefore are arranged for example on separate carriers in succession in the beam path or on a common carrier. In that respect interpenetration of the radiation filter rasters per se is not necessary.

Advantageously the first radiation filter raster is a first color raster and the first filter property is a first color and the second radiation filter raster is a second color raster and the second filter property is a second color different from the first color. It is possible, in a simple fashion, to obtain information in respect of the object scene, associated with two different colors. Color is used to denote the intensity function of a radiation passing through a color filter, in a narrow or wider spectral range, the functions of the first color differing from the function of the second color. The color can be in the visible spectral range, in the infrared range, or in another range which is meaningful for obtaining information. For moving an image of the color rasters on the detector arrangement, the filter unit can be moved relative to the optical unit. It is sufficient if the moved image of the color rasters only partially images the color rasters.

Objects in front of a heavily structured background or camouflaged or disguised objects can be recognised particularly well by means of image-processing means, from two images of the object scene involving different polarization directions. For that purpose the first radiation filter raster is advantageously a first polarization filter raster and the first filter property is a first polarization direction and the second radiation filter raster is a second polarization filter raster and the second filter property is a second polarization direction different from the first polarization direction.

A particularly high level of information content for elucidation purposes can be achieved if the first radiation filter raster is a polarization raster and the first filter property is a polarization direction and the second radiation filter raster is a color raster and the second filter property is a color. Subtracting an image filtered with the polarization raster from an unfiltered image means that it is possible to forego a second polarization raster. Similarly, subtraction of an image filtered by means of a for example color high-pass filter from an unfiltered image makes it possible to attain a color low-pass filter image. In that way, it is possible to obtain information about color and polarization of the object scene, with only two radiation filter rasters. The computing expenditure can be reduced by the provision of two polarization rasters and in addition two color rasters.

The radiation filter rasters can be arranged in or very close to the image plane of the detector arrangement. Desirably however the two radiation filter rasters are arranged in an intermediate image plane. In that way the geometry of the raster patterns is substantially sharply imaged on the detector so that it is easily possible to provide for an association of detector units with each raster, even without involving direct spatial proximity. By reading out the respective detector units, it is possible in that way to obtain an overall image, without a high level of computing expenditure.

A particularly slight necessary movement of the radiation filter rasters and therewith very rapid recording of a plurality of images can be achieved if the detector units each correspond to a respective detector cell, the images of the two radiation filter rasters are produced on the detector units, and a representation of a raster width on the detector units corresponds to a dimension of a detector unit. In that way the radiation filter rasters only have to be moved by a very small distance, which can be achieved easily, quickly and precisely, for example by means of a piezoelectric control unit. The raster width can be the line width of a line grating-like radiation filter raster or an edge length of a chessboard square. It is sufficient if the images of the radiation filter rasters are only partially produced on the detector units.

In a further configuration of the invention it is proposed that the first radiation filter raster has a first light-transmitting radiation filter surface and the second radiation filter raster has a second light-transmitting radiation filter surface and the two radiation filter surfaces are of different sizes. In that way the intensity of the radiation passing through the two radiation filter surfaces can be suitably adapted to the detector used. Thus for example in the visual and in particular in the infrared spectral range, the photon flux in a long-wave color is greater than that in a shorter-wave spectral range. To provide that the detector is utilised to the best possible extent however it is desirable for the photon flux to be kept substantially equal after sampling of differing information (color or polarization) on a detector unit. That can be achieved if the color surface which is transmissive in the longer-wave spectral range is of a smaller area than the color surface which is transmissive in the shorter-wave spectral range. The nature of the surface area ratio is desirably adapted to the expected photon fluxes and the detector used. For physical reasons, it is also possible for different fluxes to occur through polarization filtration, so that such an adaptation possibility is advantageous.

It is also proposed that the radiation filter rasters each have a light-transmitting radiation filter surface and the filter unit includes an aperture or screen structure for delimiting one of the radiation filter surfaces so that one of the radiation filter surfaces is larger than the other. The screen structure can provide that a color surface which is light-transmitting for example in the longer-wave spectral range, with a high photon flux per surface area, can be reduced, so that the photon flux for each color raster is approximately equal for all color rasters. The screen structure can be adapted to the use of the apparatus and to the detector arrangement.

Advantageously the screen structure is movable relative to at least one radiation filter raster. The screen structure can in that way be adapted to the incident light intensity or to the incident light intensity to be expected so that it is possible to ensure that the detector arrangement is well used, with a high degree of flexibility. The screen structure is movable for example by a motion unit for moving the screen structure relative to the color raster. Such a motion unit can be a piezoelectric control device or another control device which appears suitable to the man skilled in the art.

A further advantage can be achieved if the screen structure includes at least two screen gratings which are arranged symmetrically relative to a radiation filter raster and which in particular are mounted movably in symmetrical relationship with the radiation filter raster. The radiation filter raster can be covered symmetrically, for example on both sides, by the screen structure, so that a remaining raster gap can fall symmetrically on a detector arrangement. The apparatus can be flexibly adapted to the respective use involved, by virtue of the movable mounting of the symmetrical screen gratings.

An additionally increased level of resolution can be achieved if the apparatus includes an aperture or screen raster having a number of screen units, wherein each screen unit is associated with a detector unit and includes a number N of screen sub-units and wherein a screen sub-unit is light-transmitting and movable stepwise relative to the filter unit and N−1 sub-units are impervious to light. It is possible in that way to shade off radiation by N−1 screen sub-units so that only radiation through a screen sub-unit is passed on to a detector unit and in that way the image of a for example color partial image can be formed on the detector unit. The movement of the screen sub-unit in such a way that N color partial images are successively formed on the detector unit can provide that a color image with an N-times resolution can be produced from those N color partial images. The association of the screen units with the detector unit is effected by way of optical imaging of the screen units on the detector units. For movement of the radiation-transmitting screen sub-unit, the screen raster as a whole can be moved by a distance which corresponds for example to a dimension of that screen sub-unit. It is likewise possible to move only the screen sub-unit, for example if a previously opaque screen sub-unit is switched into a light-transmitting condition and the previously light-transmitting screen sub-unit is switched into an opaque condition. Such a configuration which can be achieved for example by an LCD technology (Liquid Crystal Display) makes it possible to entirely forego mechanical movement of the screen raster.

Advantageously a dimension of the screen sub-units, at least of the light-transmitting screen sub-unit, is equal to a dimension of one of the radiation filter rasters. In that way it is possible to produce firstly an overall image of a first filter property and then an overall image of a second filter property. In addition the screen raster and the radiation filter rasters can be provided with the same very fine structure and movement of the radiation filter rasters can be kept small.

It is further proposed that the light-transmitting screen sub-unit is formed by a lens. In that way, a function of influencing the beam path can additionally be attributed to that screen sub-unit.

The radiation filter rasters are formed to the same advantage by lens arrays with filtering lens. In particular the combination of screen sub-units and filtering, for example colored, lens make it possible to deflect a beam path by a very small movement of the lens, in such a way that it is possible to achieve an additional increase in resolution by the use of partial images which are oriented in different directions.

The object in relation to the method of the invention is attained by a method of the kind set forth in the opening part of this specification in which, in accordance with the invention, a first image of a first filter property is produced on a first detector unit and a second image of a second filter property is produced on a second detector unit, a third image of the first filter property is produced on the second detector unit and a fourth image of the second filter property is produced on the first detector unit, and a first overall image is produced from the first and third images and a second overall image is produced from the second and fourth images. In that way, using only one detector arrangement, it is possible to produce two overall images involving differing filter property very easily and rapidly, from which a high level of information content can be extracted, in particular by way of image-processing means, for example by image subtraction.

Desirably, firstly the first and second image are produced on the detector arrangement, in particular simultaneously, and then the third and fourth image are produced on the detector arrangement, in particular simultaneously. It is possible to implement particularly simple production of two overall images involving different filter properties.

A multiplication of the level of resolution can be achieved by a procedure whereby, to produce the first image, a first partial image is produced through a screen sub-unit of an screen raster on the first detector unit and after a respective stepwise movement of a screen sub-unit a number N−1 of further partial images are produced on the first detector unit and the first image is produced from the N partial images. As described above, N=4 or another number of partial images, which appears suitable to the man skilled in the art, can be produced. Production can be implemented purely electronically and without involving visual representation. Optionally, one or more radiation filter rasters can be moved with the screen sub-unit. In that way it is possible firstly for an overall image with a first filter property to be completely produced and then for an overall image with a second filter property to be completely produced.

Advantageously the N partial images of the first image and the N partial images of the third image are respectively produced in parallel relationship on the first detector unit and the second detector unit respectively. In that way firstly an overall image of a first filter property can be produced completely and then an overall image of a second filter property can be produced completely. In that case a first partial image of the first image is produced in parallel relationship with the first partial image of the third image on the detector unit, then the second partial image of the first image in parallel relationship with the second partial image of the third image, and so forth. Alternatively the N partial images of the first image and the N partial images of the second color image can be respectively produced in parallel relationship on the first detector unit and the second detector unit respectively. In that case fewer but somewhat larger movements of the radiation filter rasters are necessary.

### BRIEF DESCRIPTION OF THE DRAWINGS

Further advantages will be apparent from the specific description hereinafter. The drawing shows a number of embodiments by way of example of the invention. The drawing, the description and the claims set forth numerous features in combination. The man skilled in the art will desirably also consider the features individually and combine them to form appropriate further combinations.

In the drawings:

FIG. 1 is a diagrammatically illustrated beam path in an apparatus for producing a representation of an object scene,

FIG. 2 shows two radiation filter rasters and four detector units,

FIG. 3 shows the radiation filter rasters of FIG. 2 in a displaced position,

FIG. 4 shows four radiation filter rasters and four detector units,

FIG. 5 shows two radiation filter rasters with a screen structure,

FIG. 6 shows two radiation filter rasters with two movable screen gratings,

FIG. 7 shows four radiation filter rasters with four movable screen gratings,

FIG. 8 shows two radiation filter rasters, a screen structure, four detector units and a screen raster,

FIG. 9 shows the radiation filter rasters in a position displaced with respect to FIG. 8,

FIG. 10 shows two further radiation filter rasters with a screen raster and detector units,

FIG. 11 shows the radiation filter rasters and the screen raster in a position displaced with respect to FIG. 10,

FIG. 12 shows the screen raster in a position displaced with respect to FIG. 11,

FIG. 13 shows the radiation filter raster and the screen raster in a position displaced with respect to FIG. 12,

FIG. 14 shows radiation filter rasters and screen sub-units in the form of lenses,

FIG. 15 shows a beam path which is somewhat displaced with respect to FIG. 1,

FIG. 16 shows an arrangement for multiplying the visible field of vision, and

FIG. 17 shows a control arrangement for moving color rasters and screens.

### DETAILED DESCRIPTION OF THE INVENTION

FIG. 1 shows a beam path of an apparatus 2 for producing a representation of an object scene having an optical unit 4 in the form of a primary objective, an intermediate image plane 6, an optical unit 8 in the form of a secondary objective and a detector device 10. The secondary objective serves for forming the image of the object scene on the detector device 10 and the primary objective serves for forming the image of the object scene in the intermediate image plane 6 (and thus also on the detector device 10). The detector device 10 includes a detector arrangement 12 and a read-out unit 14 for determining electrical charges in the detector arrangement and forwarding corresponding signals to an evaluation apparatus (not shown).

Arranged in the intermediate image plane 6 is a filter unit 16 with a first radiation filter raster (horizontal hatching) and a second radiation filter raster (vertical hatching). The radiation filter rasters can be polarization filter rasters, wherein the first radiation filter raster allows for example only horizontally polarised radiation to pass and the second radiation filter raster allows only vertically polarised radiation to pass. The radiation filter rasters mutually penetrate each other insofar as stripes of the two radiation filter rasters are disposed alternately in mutually juxtaposed relationship on a carrier. Interpenetration can also be implemented in such a way that the two radiation filter rasters are arranged on separate carriers one behind the other in the beam path as shown in FIG. 1.

It is also possible for the two radiation filter rasters to be respective color rasters 18r, 18b which provide for color filtering of incident radiation. The following Figures are described essentially by means of the example of color rasters, without that entailing a limitation of the radiation filter rasters to color rasters and the images obtained to color images.

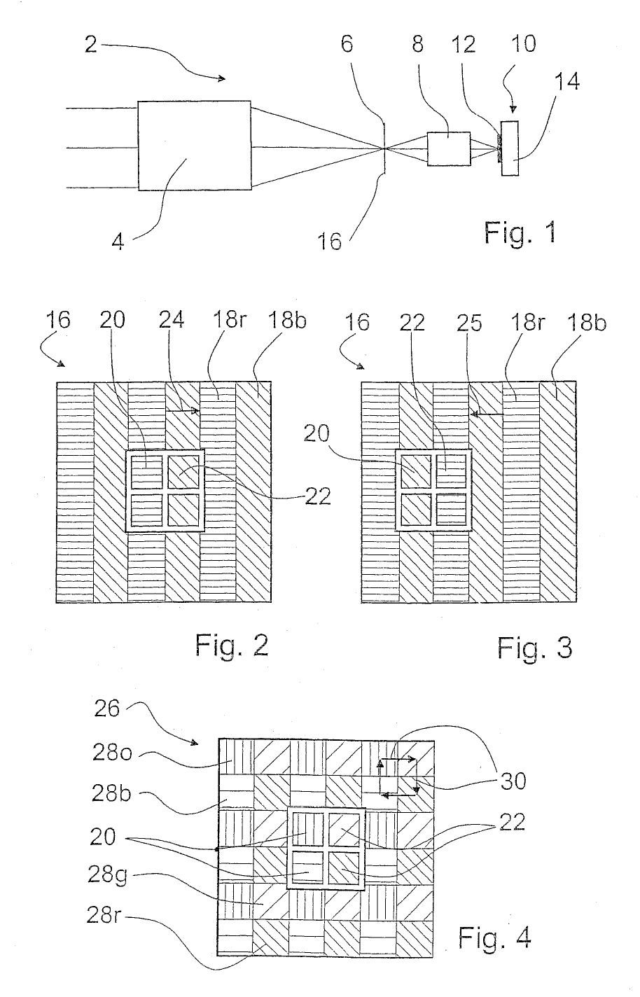

FIGS. 2 and 3 each show two color rasters 18b, 18r. The two color rasters 18r, 18b are light-transmitting in the long-wave infrared range (8-10 μm), wherein the first color raster 18r is light-transmitting in a narrow spectral range around 10 μm and the second color raster 18b is light-transmitting in a narrow spectral range around 8 μm. For simplification purposes the long-wave and first color raster 18r is therefore referred to hereinafter as the red color raster 18r and the short-wave, second color raster 18b is referred to as the blue color raster 18b, without that intending to denote spectral limitation to a given color. The apparatus 2 is provided in particular for detecting objects which involve a temperature of about 350 K. The radiation emitted by such objects has a photon flux which is of approximately the same strength in the region of 8 μm as in the region around 10 μm. To indicate those substantially identical photon fluxes the hatching of the color rasters 18r, 18b in FIGS. 2 and 3 involves approximately equal hatching spacings. The two color rasters 18r, 18b each include stripe-shaped, light-transmitting color surfaces which are 40 μm wide. The two color surfaces are of equal size, in which respect it is possible without any difficulties, in the case of a differing photon flux in the longer-wave range relative to the shorter-wave range, for the color surface with a greater photon flux to be of smaller size than the color surface provided for a spectral range involving a lower photon flux.

The detector arrangement 12 has a number of detector units 20, 22 of which four detector units 20, 22 are diagrammatically illustrated in each of FIGS. 2 and 3. Each detector unit 20, 22 is formed by a detector cell and is of a side length of about 40 μm. The entire detector arrangement 12 comprises 256×256 detector cells or detector units 20, 22, of which only four are illustrated for the sake of clarity. The color rasters 18r, 18b are imaged on the detector arrangement 12 by virtue of the positioning of the filter unit 16 in the intermediate image plane 6. That image of the color rasters 18r, 18b on the detector units 20 is shown in FIGS. 2 and 3. The Figures therefore do not show the color rasters 18r, 18b as such, but the image thereof in the image plane of the detector arrangement 12. An interpretation of the Figures, which is equally well possible but which is not further pursued in the description hereinafter, would involve image production of the detector units 20 on the specifically illustrated color rasters 18r, 18b.

In FIG. 2 the two left-hand detector units 20 are irradiated with ‘red’ light in the region of 10 μm, which has passed through the red color raster 18r, and the two right-hand detector units 22 are irradiated with ‘blue’ light in the region of 8 μm, which has passed through the blue color raster 18b.

At a first moment in time the filter unit 16 is arranged in the intermediate image plane 6 in such a way that the image of the color rasters 18r, 18b impinges on the detector units 20, 22, as illustrated in FIG. 2. In that case a first color image of red color is recorded on the two left-hand detector units 20 and a second color image of blue color is recorded on the two right-hand detector units 22. In this case the part of the color rasters 18r, 18b, which is illustrated in the detector units 20, 22 in FIG. 2, corresponds to the first and the second color image respectively. After a time which is matched to the detector units 20, 22 the filter unit 16 is moved in the intermediate image plane 6 in such a way that the image thereof is displaced on the detector units 20, 22 a distance in the direction of the arrow 24. The resulting image on the detector units 20, 22 is shown in FIG. 3. In that position once again for a certain time a third color image of a red color is recorded on the right-hand detector units 22 and a fourth color image of blue color is recorded on the left-hand detector units 20. In that case the part of the color rasters 18b, 18r represented in the detector units 20, 22 in FIG. 3 corresponds to the fourth and third color images respectively. The filter unit 16 is then moved back again in the intermediate image plane 6 so that the image of the color rasters 18r, 18b is displaced in the direction of the arrow 25 on the detector units 20, 22. The position reached corresponds to the position shown in FIG. 2 of the image of the color rasters 18r, 18b at the first moment in time. Now, new color images of a red color can be recorded by the left-hand detector units 20 and new color images of a blue color can be recorded by the right-hand detector units 22. To produce an overall color image the first and third color images of a red color can be assembled and the second and fourth color images of a blue color can also be assembled to form an overall color image, by means of electronic data processing. In each case therefore there is an overall color image, recorded by 256×256 detector units 20, 22, of a red color, and an overall color image of a blue color, for further evaluation.

FIG. 4 shows the representation of a further filter unit 26 which includes four radiation filter rasters. Two of the radiation filter rasters are color rasters 28r, 28b and two of the radiation filter rasters are polarization filter rasters 28s, 28w. The color raster 28r referred to as the red color raster 28r is light-transmitting in a long-wave spectral range and the color raster 28b is light-transmitting in a short-wave spectral range and therefore is identified hereinafter as the blue color raster 28b. The polarization rasters 28s and 28w are referred to as vertical polarization raster 28s and horizontal polarization raster 28w. The width of the hatchings again indicates the strength of the photon flux through the color rasters 28r, 28b and the polarization rasters 28s, 28w.

In this embodiment, instead of the filter unit 16, the filter unit 26 is disposed in the intermediate image plane 6 and is moved by a control arrangement (not shown) in such a way that the image of the filter unit 26 on the detector units 20, 22 is displaced stepwise in the manner illustrated by the four arrows 30. In this case, in four successive time portions, the four detector units 20, 22 can be exposed in the four different filter properties in such a way that each of the detector units 20, 22 can provide for recording a respective image of each filter property, that is to say color and polarization direction. Each four images of the same filter property can be assembled to form an overall image so that, after the four time portions, four overall images are present in the two colors red and blue and the two polarization directions horizontal and vertical. Those four overall images can be passed to the evaluation unit for further evaluation.

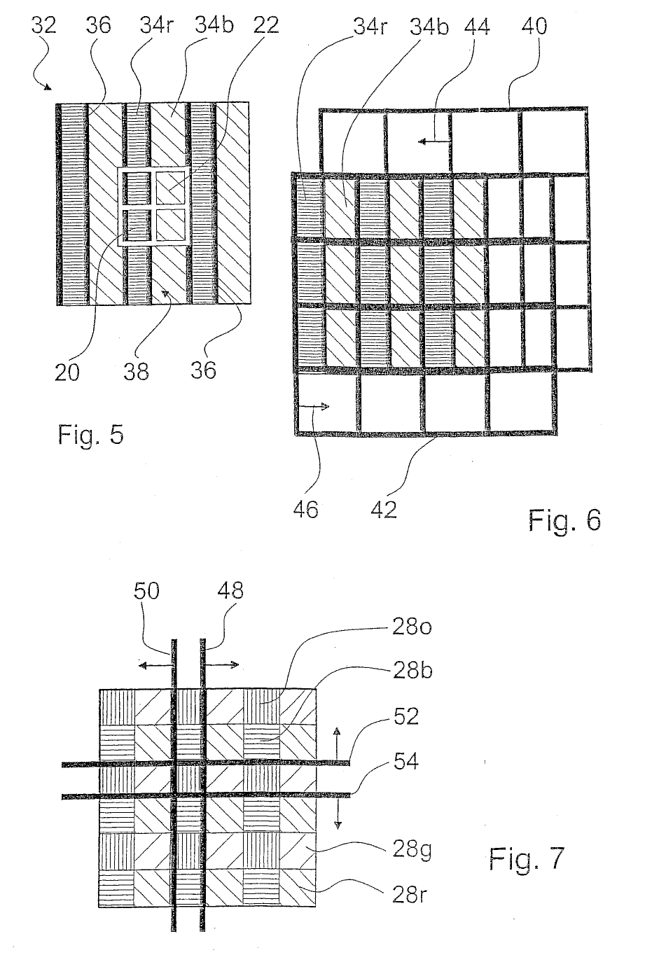

FIG. 5 shows the image of a further filter unit 32 with two color rasters 34r and 34b. The two color rasters 34r, 34b are light-transmitting in the medium-wave infrared range, in which case the color raster 34r referred to as the red color raster 34r is light-transmitting in a spectral range around 5 μm and the color raster 34b referred to as the blue color raster 34b is light-transmitting in a spectral range around 3 μm. The filter unit 32 is designed to detect objects involving a temperature of about 500 K, wherein such objects radiate in such a way that the photon flux in the range of 5 μm is approximately twice as great as that in the range of 3 μm, which is symbolically indicated by the density of the hatching in FIG. 5. The two color rasters 34r, 34b include dielectric layer systems which are vapour deposited on to a silicon substrate. Light-impervious metallic barrier layers 36 are also produced by vapour deposition between the color rasters 34r, 34b and, as a screen structure 38, delimit the light-transmitting color surfaces of the color rasters 34r, 34b in such a way that the color surface of the red color raster 34r is about half smaller than that of the blue color raster 34b. In that way the detector units 20, 22 are acted upon by approximately the same photon flux, upon exposure through the red color raster 34r and the blue color raster 34b respectively. By means of the primary objective 4 and/or the secondary objective 8, the photon flux on to the detector units 20, 22 can be adjusted in that way into a respective favourable range. The mode of operation of the filter unit 32 and the screen structure 38 corresponds to the mode of operation described with reference to FIGS. 2 and 3.

An alternative embodiment of screen structures 40, 42 is shown in FIG. 6. In this case the screen structures 40, 42 are vapour deposited on to a respective separate substrate so that the screen structures 40, 42 are movable relative to each other. The color rasters 34r, 34b are produced by vapour deposition on a third substrate so that the image of the filter units 32 is movable relative to the image of the screen structures 40, 42. The screen structures 40, 42 are also arranged in the intermediate image plane 6 of the apparatus 2 for producing a representation of an image scene. The screen structures 40, 42 are identical to each other, FIG. 6 only showing the screen structure 40 as being somewhat thinner for the sake of enhanced clarity. A reduction in the size of the color surface of the red color raster 34r is achieved by a movement of the screen structure 40 towards the left as indicated by the arrow 44 and a movement of the screen structure 42 towards the right as indicated by the arrow 46. Depending on which objects are to be investigated, involving which temperature, the two screen structures 40, 42 can move into a suitable position and thus the photon flux on the detector units 20, 22 can be adjusted in such a way that the color surface of the red color raster 34r is suitably shaded.

An arrangement provided with four screen structures 48, 50, 52, 54 which are mounted movably relative to each other is shown in FIG. 6. Therewith, the images of the two color rasters 28r, 28b and the two polarization rasters 28s, 28w can be very easily and flexibly shaded in a desired manner so that the photon flux incident on the detector units 20, 22 can be optimised for objects to be investigated. The screen structures 48, 50, 52, 54 are only diagrammatically illustrated in FIG. 7 and can be designed similarly to the screen structures 40, 42 or in another fashion which seems appropriate to the man skilled in the art.

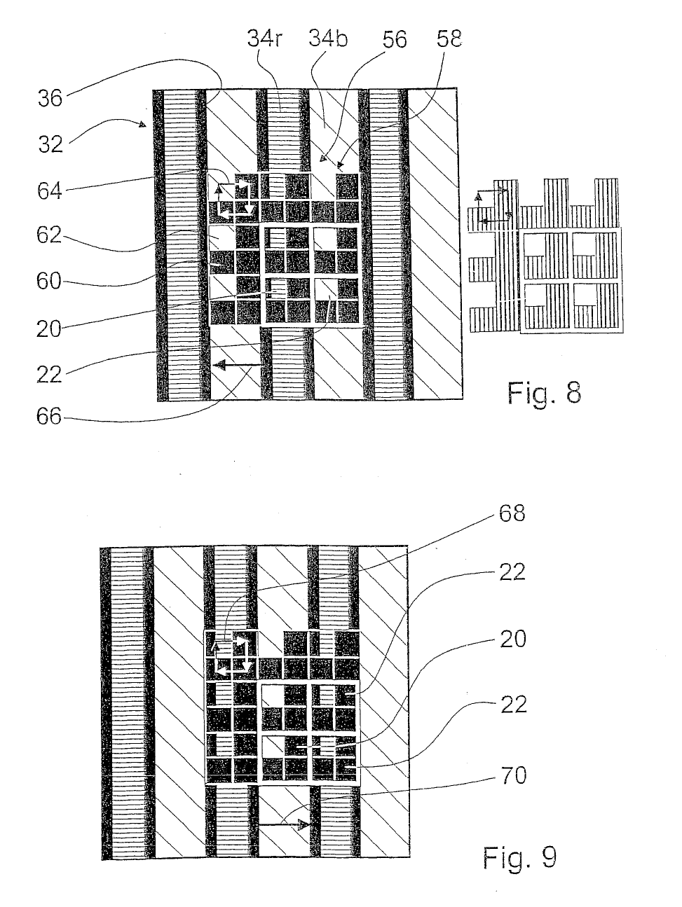

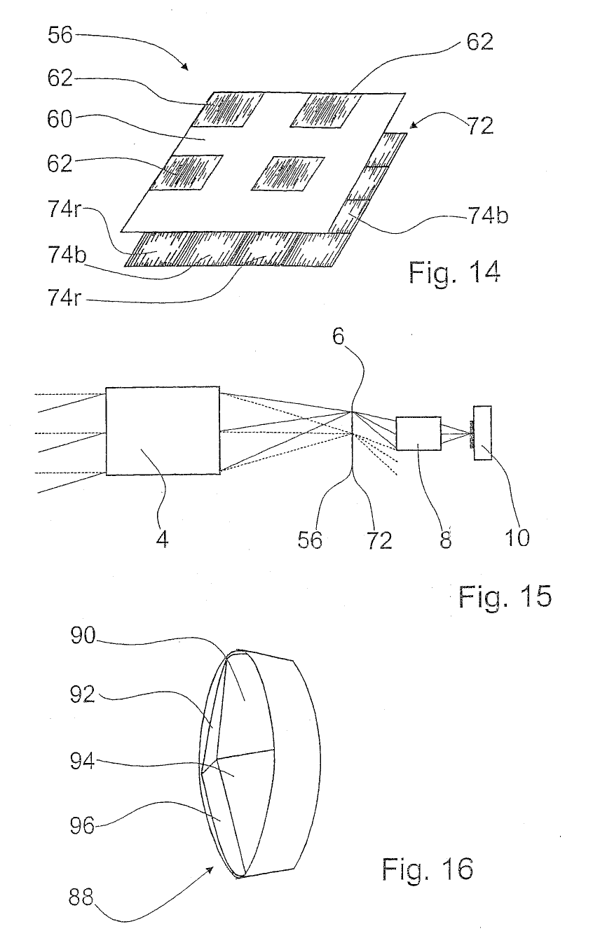

FIG. 8 shows an arrangement like that illustrated in FIG. 5, additionally showing a screen raster 56 or the image thereof produced on the detector units 20, 22. The screen raster 56 is also arranged in the intermediate image plane 6 and has somewhat more than 256×256 screen units 58, of which only nine are shown in FIG. 8. Each of the screen units 58 has four screen sub-units 60, 62, of which only one respective screen sub-unit 62 is light-transmitting. Each of the screen units 58 is associated with a respective detector unit 20, 22 so that a light-transmitting screen sub-unit 62 is also associated with each detector unit 20, 22. If the detector units 20, 22 are provided only with a single detector cell, then the light passing through the respective light-transmitting screen sub-unit 62 is suitably registered by that single detector cell. To provide for suitability for detector units 20, 22 each with a respective number of detector cells, the image produced in respect of the light-transmitting screen sub-unit 62 can be enlarged by a suitable lens structure, as is shown in FIG. 14, so that the image produced in respect of the light-transmitting sub-unit 62 respectively completely substantially fills the area of the detector units 20, 22.

To produce a first red color image, a first color partial image is produced on the detector units 20 by those screen sub-units 62 which belong to the screen units 52 associated with the left-hand detector units 20. In that respect the part of the color raster 34r shown in the detector units 20 in the screen sub-units 62 in FIG. 8 corresponds to the first color partial image. Simultaneously a first blue color partial image is produced on the detector units 22 through the screen sub-units 62 associated with the right-hand detector units 22. In that case the part of the color raster 34b shown in the detector units 22 in the screen sub-units 62 in FIG. 8 corresponds to the second color partial image. Then the screen raster 56 is displaced a distance indicated by an arrow 64, towards the right. Now the image of another portion of the object scene being viewed is produced on the detector units 20, 22 through the light-transmitting screen sub-units 62. After the second red and blue color partial images have been recorded and after the corresponding charge values have been read out of the detector units 20, 22 the screen raster 56 is displaced by the same distance but downwardly so that the in turn new color partial image of new portions of the object scene is produced on the detector units 20, 22. After recording has been implemented by the detector units 20, 22, the screen raster 56 is displaced towards the left and third color partial images are produced on the detector units 20, 22. For producing fourth red and blue color partial images, the screen raster 56 is displaced towards the left in order to be moved upwardly into the starting position, after that fourth color partial image has been registered. In that way four red color partial images can be produced on each detector unit 20 and in a similar manner simultaneously therewith four blue color partial images can be produced on the detector units 22. Red and blue color images respectively can be assembled from those respective four color partial images.

In a next method step for producing a representation of an object scene, the filter unit 32 is moved towards the left as indicated by the arrow 66 so that the images of the color rasters 34r, 34b come to lie on the detector units 20, 22, in a manner as shown in FIG. 9. Then, in a similar fashion to the description in relation to FIG. 8, four further color partial images are registered on each detector unit 20, 22, in which case the screen raster 56 is again moved stepwise four times as indicated by the arrows 68. For positioning the filter unit 32 in the starting position, the filter unit 32 is then moved towards the right in a direction indicated by the arrow 70 so that the image of the color rasters 34r, 34b, as shown in FIG. 8, comes to lie on the detector units 20, 22. The respective four color partial images per detector unit 20, 22, which were obtained as described with reference to FIG. 9, can be assembled to form a respective color image, in which respect the blue color images are to be associated with the detector units 20 and the red color images are to be associated with the detector units 22.

Then the red color images of the detector units 20, as shown in FIG. 8, and the red color images of the detectors units 22, as shown in FIG. 9, are assembled to form a red overall color image. Similarly the blue color images can be assembled to form an overall color image so that after a total of eight recordings of color partial images, two complete overall color images can be produced. It is possible in that way, in eight image cycles, both to multiply the level of resolution by means of the screen raster 56 and also to obtain two differently colored overall color images by means of the filter unit 32. When using a commercially available detector arrangement with 256×256 detector units and an image rate of Hz, an increase in resolution to 512×512 effective pixels in a two-color image at 100 Hz is thus possible.

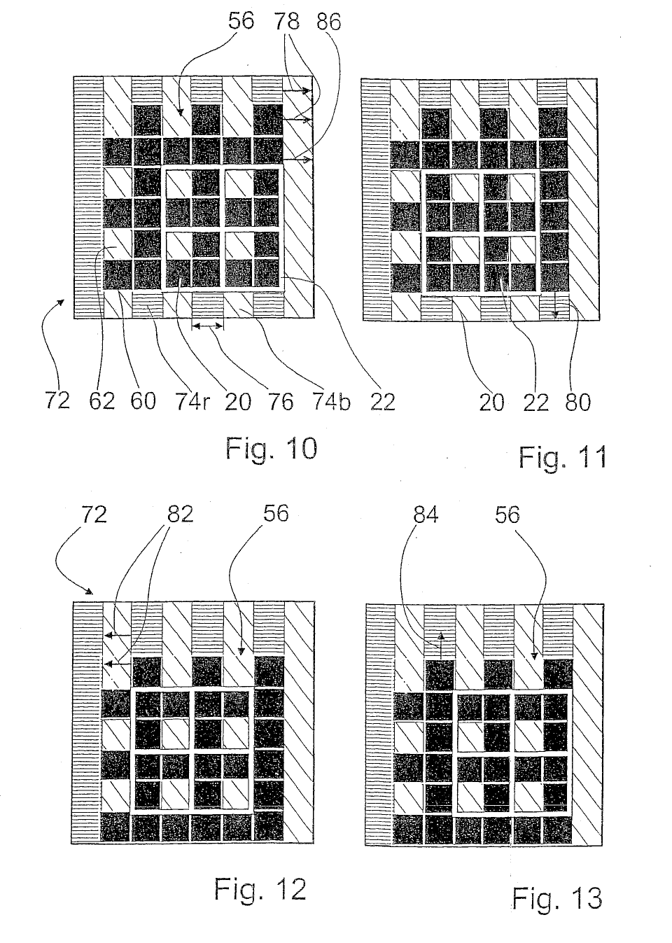

An alternative arrangement of detector units 20, 22, screen rasters 56 and filter unit 72 is shown in FIGS. 10 to 13. In this case the detector units 20, 22 and the screen raster 56 correspond to the described components shown in FIGS. 8 and 9. The filter unit 72 however includes a red color raster 74r and a blue color raster 74b which are each only half the width of the color rasters 34r, 34b. By virtue of that, a dimension 76 of the screen sub-units 60, 62 is equal to the width of the color rasters 74r, 74b. For the sake of simplicity, a screen structure for covering the red color surface of the red color rasters 74r is not shown in FIGS. 10 to 13.

When the screen raster 56, the detector units 20, 22 and the filter unit 72 are positioned as shown in FIG. 10, a first blue color partial image can be respectively recorded on each of the detector units 20, 22. Then, the filter unit 72 and the screen raster 56 are moved towards the right in the manner shown by the arrow 78 so that the image produced in respect of the filter unit 72 and the screen raster 56 on the detector units 20, 22 appears as shown in FIG. 11. In that position, a respective second blue color partial image which shows another portion from the object scene can be recorded on each of the respective detector units 20, 22. Then, only the screen raster 56 is moved downwardly as indicated by the arrow 80 in such a way that the image of the screen raster 56 moves into a position as shown in FIG. 12. In that position, a respective third color partial image representing a further portion from the object scene can be recorded by the detector units 20, 22. For recording respective fourth blue color partial images, the screen raster 56 and the filter unit 72 are now moved towards the left as indicated by the arrows 82 so that the image of the screen raster 56 and the filter unit 72 are disposed as shown in FIG. 13. After recording of the respective fourth blue color partial image, only the screen raster 56 is moved upwardly into the starting position shown in FIG. 10, as indicated by the arrow 84.

In that way, for each detector unit 20, 22, the procedure provides for recording four respective blue color partial images which can be assembled to constitute a respective blue color image per detector unit 20, 22. Or, in other words: four blue color partial images of a first color image are produced on the detector units 20 and four blue color partial images of a third color image are produced in parallel on the detector units 22. A blue overall color image can be produced from the totality of the blue (first and third) color images. In that way, a blue overall color image can be completely produced and fed to an evaluation unit before the procedure begins with recording red color partial images for the production of a red overall color image.

After recording of all blue partial images is completed, the light-transmitting screen sub-units 62 can be laid over the red color raster 74r by virtue of movement of the screen raster 56 as indicated by the arrow 86 and leaving the filter unit 72 in its position as shown in FIG. 10. To produce four red color partial images per detector unit 20, 22, the screen raster 56 and the filter unit 72 are respectively moved stepwise in a similar manner to the procedure described with reference to FIGS. 10 to 13.

A perspective view of the screen raster 56 and the filter unit 72 is shown in FIG. 14. The screen raster 56 includes a metallic layer which is produced by vapour deposition on a carrier substance and which forms the light-impervious screen sub-units 60. The light-transmitting screen sub-units 62 are each formed by a respective micro-convergent lens. Those micro-convergent lenses are for example biconvex lenses. The blue color raster 74b comprises a number of micro-divergent lenses arranged in a row with each other, for example biconcave lenses, of which five lenses are visible in FIG. 14. In a similar configuration the red color rasters 74r are formed by arrangements in rows with each other of red micro-divergent lenses of which two are visible in FIG. 14.

The arrangement of the micro-convergent lenses and the micro-divergent lenses in the intermediate image plane 6 means that radiation passing through the lenses can be deflected in a manner as shown in FIG. 15. With an exactly aligned position of the lenses relative to each other, a beam path is produced as shown in FIG. 1. In the case of a slight movement of the screen sub-units 62 out of the optical central axis of the lenses of the color rasters 74r, 74b, the radiation passing through the lenses is deflected downwardly for example as shown in FIG. 15. By virtue thereof, an image portion indicated by broken lines, on the left-hand side of the primary objective 4, is no longer deflected by the beam path shown in broken lines between the primary objective 4 and the secondary objective 8 into the secondary objective 8 as shown in FIG. 1, but is guided in such a way that the radiation does not impinge on the detector device 10. Instead, radiation from a direction in which the solid lines pass to the left of the primary objective 4 is deflected on to the detector device 10 and the detector units 20, 22.

A suitable choice in respect of the micro-convergent lenses of the screen sub-units 62 and the micro-divergent lenses of the color rasters 74r, 74b can provide for an increase in size of the representations of the two above-described color partial images, in such a way that the color partial images respectively fill the area of the detector units 20, 22 entirely or to a desired extent. In that case, in the event of a movement of the screen raster 56, the screen sub-units 62 are also to be minimally displaced relative to the lenses of the color rasters 74r, 74b in such a way that the beam path deflected by the screen sub-units 62 remains focused on to the detector units 20, 22.

A further increase in resolution by for example the factor of 4 can be achieved by the use of a primary objective 4 as shown in FIG. 16. That primary objective 4 has an outer lens 88 with a prism structure in the form of a shallow pyramid. That pyramid comprises four shallow sectors 90, 92, 94, 96 through which the images of the beam paths from various portions of the object scene are formed in mutually superposed relationship in the intermediate image plane 6. Displacement of the screen sub-units 62 relative to the lenses of the color rasters 74r, 74b makes it possible to select a respective beam path from the sectors 90, 92, 94, 96, which is passed to the detector device 10. Displacement of the screen sub-units 62 relative to the lenses of the color rasters 74r, 74b for switching over between the various sectors is in that case small in relation to the dimension of the screen sub-units 62.

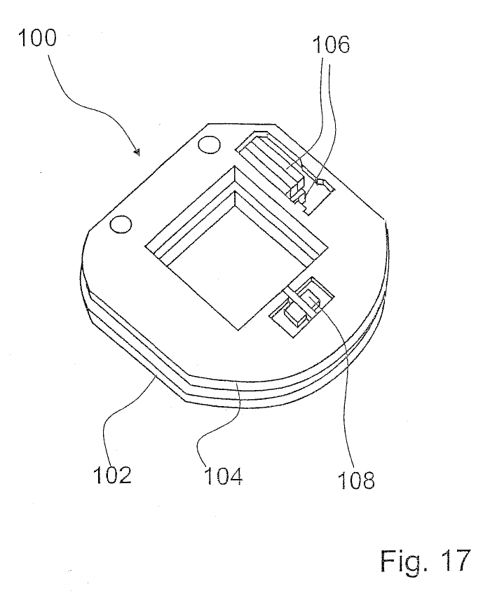

A diagrammatic representation of a control unit or motion unit 100 for moving for example the filter unit 32 and the screen raster 56 (FIG. 8) in the intermediate image plane 6 is shown in FIG. 17. The motion unit 100 includes two frames 102, 104, of which the frame 102 surrounds the filter unit 32 and the frame 104 the screen raster 56. The filter element 32 and the screen raster 56 are not shown for the sake of clarity in FIG. 17. The filter unit 32 and the screen raster 56 are mounted within the frames 102 and 104 respectively movably in such a way that they can be reciprocated by a respective piezoelectric control element 106 within the respective frame 102, 104. Each of the piezoelectric control elements 106 has stacks of piezoelectric elements which are supported on the frames 102, 104. The stroke of the piezoelectric elements is transmitted by a step-up and deflection lever transmission arrangement (not shown) to the filter unit 32 and the screen raster 56 respectively. In that case the stroke of the stacks of piezoelectric elements is only a few μm. The control travel of the filter unit 32 and the screen raster 56 relative to the frames is measured by means of a capacitive travel measuring sensor 108. The travel measuring sensor 108 and the piezoelectric control elements 106 form measuring sensor devices and the control member of a regulating circuit (not shown), by means of which the control travel of the filter unit 32 and the screen raster 56 can be regulated to a predetermined value.

### REFERENCES

2 apparatus
4 unit
6 intermediate image plane
8 unit
10 detector device
12 detector arrangement
14 read-out unit
16 filter unit
18r color raster
18b color raster
20 detector unit
22 detector unit
24 arrow
25 arrow
26 filter unit
28r color raster
28b color raster
28s polarization filter raster
28w polarization filter raster
30 arrow
32 filter unit
34r color raster
34b color raster
36 barrier layer
38 screen structure
40 screen structure
42 screen structure
44 arrow
46 arrow
48 screen structure
50 screen structure
52 screen structure
54 screen structure
56 screen structure
58 screen unit
60 screen sub-unit
62 screen sub-unit
64 arrow
66 arrow
68 arrow
70 arrow
72 filter unit
74r color raster
74b color raster
76 dimension
78 arrow
80 arrow
82 arrow
84 arrow
86 arrow
88 lens
90 sector
92 sector
94 sector
96 sector
100 motion unit
102 frame
104 frame
106 piezoelectric control element
108 travel measuring sensor

What is claimed is:

1. An Apparatus (2) for producing a representation of an object scene, including a detector arrangement (12) with a plurality of detector units (20, 22) and an optical unit (4, 8) for producing the image of the object scene on the detector arrangement (12), a filter unit (16, 26, 32, 72) arranged in an imaging beam path, with a first radiation filter raster with a first filter property and at least one second radiation filter raster with a second filter property different from the first filter property, wherein the first and second radiation filter rasters penetrate each other, the first radiation filter raster being a polarization raster (28s, 28w) and the first filter property being a polarization direction, the second radiation filter raster being a color raster (18b, 28b, 28r, 34b, 74b) and the second filter property being a color and including a motion unit (100) for stepwise movement of an image of the radiation filter rasters relative to the detector arrangement (12).

2. An Apparatus (2) for producing a representation of an object scene, including a detector arrangement (12) with a plurality of detector units (20, 22) and an optical unit (4, 8) for producing the image of the object scene on the detector arrangement (12), a filter unit (16, 26, 32, 72) arranged in an imaging beam path, with a first radiation filter raster with a first filter property and at least one second radiation filter raster with a second filter property different from the first filter property, wherein the first and second radiation filter rasters penetrate each other, the first radiation filter raster being a polarization raster (28s, 28w) and the first filter property being a polarization direction, the second radiation filter raster being a color raster (18b, 28b, 28r, 34b, 74b) and the second filter property being a color, the radiation filter rasters each having a respective light-transmitting radiation filter surface and the filter unit (32, 72) including a screen structure (38, 40, 42, 48, 50, 52, 54) for delimiting one of the radiation filter surfaces so that one of the radiation filter surfaces is larger than the other, and including a motion unit (100) for stepwise movement of an image of the radiation filter rasters relative to the detector arrangement (12).

3. An apparatus (2) according to claim 1, wherein the first radiation filter raster is a first color raster (18r, 28r, 34r, 74r) and the first filter property is a first colors, and the second radiation filter raster is a second color raster (18b, 28b, 34b, 74b) and the second filter property is a second color different from the first color.

4. An apparatus (2) according to claim 1, wherein the first radiation filter raster is a first polarization filter raster (28s) and the first filter property is a first polarization direction and the second radiation filter raster is a second polarization filter raster (28w) and the second filter property is a second polarization direction different from the first polarization direction.

5. An apparatus (2) according to claim 1 or 2, wherein the two radiation filter rasters are arranged in an intermediate image plane (6).

6. An apparatus (2) according to claim 1 or 2, wherein the detector units (20, 22) respectively correspond to a detector cell and the two radiation filter rasters are imaged on to the detector units (20, 22), and an image of a raster width of the radiation filter rasters on the detector units (20, 22) corresponds to a dimension (76) of a detector unit (20, 22).

7. An apparatus (2) according to claim 2, wherein the screen structure (40, 42, 48, 50, 52, 54) is movable relative to at least one of said radiation filter raster.

8. An apparatus (2) according to claim 2, wherein the screen structure (38, 40, 42, 48, 50, 52, 54) includes at least two screen gratings arranged symmetrically relative to a radiation filter raster and in particular mounted movably symmetrically relative to the radiation filter raster.

9. An apparatus (2) according to claim 1, wherein there is provided a screen raster (56) with a number of screen units (58), each said screen unit being associated with a respective said detector unit (20, 22) and including a number N of screen sub-units (60, 62), and wherein a screen sub-unit (62) is light-transmitting and is movable stepwise relative to a filter unit (32, 72), and wherein N−1 screen sub-units (60) are light-impervious.

10. An apparatus (2) according to claim 9, wherein a dimension (76) of the light-transmitting screen sub-unit (62) is equal to a dimension (76) of one of the radiation filter rasters.

11. An apparatus (2) according to claim 9, wherein said light-transmitting screen sub-unit (62) is formed by a lens.

12. An apparatus (2) according to claim 1, wherein the radiation filter rasters are formed by lens arrays with colored lenses.

13. A method of producing a representation of an object scene, in which the object scene is imaged by an optical unit (4, 8) on to a detector arrangement (12) with a plurality of detector units (20, 22), wherein a first image with a first filter property is produced on a first detector unit (20) and a second image with a second filter property is produced on a second detector unit (22), a third image with the first filter property is produced on the second detector unit (22) and a fourth image with the second filter property is produced on the first detector unit (20), and a first overall image is produced from the first and third images and a second overall image is produced from the second and fourth images, wherein, to produce the first image, a first partial image is produced on the first detector unit (20) through a screen sub-unit (62) of an screen raster (56), and after a respective stepwise movement of the screen sub-unit (62) a number N−1 of further partial images are produced on the first detector unit (20) and the first image is produced from the N partial images.

14. A method according to claim 13, wherein the N partial images of the first image and N partial images of the third image are respectively produced in parallel on the first detector unit (20) and the second detector unit (22) respectively.
